(19) United States
(12) Patent Application Publication
(10) Pub. No.: US 2026/0111637 A1
(43) Pub. Date: Apr. 23, 2026

(54) WIDEBAND EC MODEL OF PASSIVE DEVICE, METHOD AND SYSTEM OF PARAMETER EXTRACTION THEREOF

(71) Applicant: UNIVERSITY OF SCIENCE AND TECHNOLOGY OF CHINA, Hefei (CN)

(72) Inventors: Chenhong Sun, Hefei (CN); Liguo Sun, Hefei (CN); Fujiang Lin, Singapore (SG)

(21) Appl. No.: 18/922,779

(22) Filed: Oct. 22, 2024

(30) Foreign Application Priority Data
Aug. 25, 2023 (CN) 202311091416.4

(51) Int. Cl. G06F 30/3323

(52) U.S. Cl. CPC G06F 30/3323

(57) ABSTRACT

The invention discloses a wideband EC model of a passive device, a method of parameter extraction based on the wideband EC model, and a system of parameter extraction by the method. It solves the technical problems in the prior art. The coefficient relationships between the same type elements in the wideband EC model are established, making the existing independent parameters become dependent elements, effectively reducing the number and shortening the time. The coefficient relationships between the same type elements in the L-type EC model at low frequency and the wide-band EC model can improve the accuracy of parameter extraction, reduce the difficulty of parameter extraction, and improve the efficiency of circuit design. The invention introduces a method of parameter extraction for four independent lumped elements. The method uses the telegraph equation and the linear function to obtain R₀, L₀, C₀ and G₀.

### FIELD OF THE INVENTION

The present invention relates to equivalent circuit (EC) models in a integrated circuits (ICs) field, and more particularly to a wideband EC model of a passive device, a method of parameter extraction based on the wideband EC model, and a system of parameter extraction by the method.

### BACKGROUND OF THE INVENTION

An EC model is abstracted from electrical performances of a actual device in different frequency bands. The EC model can approximately reflect electrical characteristics of the actual device.

For passive devices, in the process of analyzing electrical characteristics, especially in the millimeter wave band, it can be converted into an EC model to simplify the analysis. In general, the EC model includes four basic elements, such as resistance R, inductance L, capacitance C, and conductance G. Then, for the EC model, the most important content is to establish an accurate and simple model topology and parameter extraction method, that is, whether the EC structure can accurately characterize the physical characteristics of devices in different frequency bands, and accurately extract the values of each element in the EC according to the relevant parameter extraction formula.

For comprehensive consideration in the prior art, the general practice is to use the wideband EC model to analyze the electrical characteristics of each frequency band passive device. So it is necessary to extract the parameters of the wideband EC model. However, the existing wideband EC model has many parameters, and the higher the frequency band, the more the number of parameters, the more complicated the extraction formula and other problems.

In addition, the traditional parameter extraction method has some problems in its reference results. For example, negative numbers will appear in R, L, C and G extracted by empirical method, which obviously has no practical physical significance. In the R, L, C and G extracted from the physical-based method, the R and L representing the skin effect and proximity effect vary with the frequency band, so it is difficult to determine the actual values.

Therefore, the present invention designed a new wideband model and a simple and accurate model parameter extraction method. By establishing the element coefficient relationship between the low-band (DC˜3 GHZ) L-type EC model and the wideband EC model, the RF characteristics of passive devices in wideband (millimeter wave to terahertz frequency band) can be characterized and the number of parameter extraction can be effectively reduced. It is reduced for the difficulty of parameter extraction and improved for accuracy.

### SUMMARY OF THE INVENTION

The object of the present invention is to provide a wideband EC model of a passive device to solve the problems of large number of parameters, large amount of calculation and inaccurate results when using a traditional wide-band EC model to characterize the characteristics of passive devices from millimeter wave to terahertz. Another object of the present invention is to provide a parameter extraction method based on the wideband EC model. The third object of the present invention is to provide a parameter extraction system by the parameter extraction method.

The present invention provides a wideband EC model of a passive device, including:
a series branche circuit, comprising N series branches, N≥2; all series branches having the same elements; the N'th-order series branche comprising the N'th resistance R_{N} and the N'th inductance L_{N} in series; all series branches being in parallel except the second-order series branche and the third-order series; the second-order series branche being in parallel with the first resistance R₁, the third-order series branche being in parallel with the first inductance L₁; and
a parallel branche circuit, in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series.

The present invention further provides a method of parameter extraction, including:
the first step, establishing an L-type EC model at low frequency of the passive device, and a wideband EC model; the L-type EC model comprising an EC resistance R₀, an EC inductance L₀, an EC capacitance C₀, and an EC conductance G₀; the wideband EC model comprising a series branche circuit and a parallel branche circuit; the series branche circuit comprising N series branches, N≥2; all series branches having the same elements; the N'th-order series branche comprising the N'th resistance R_{N} and the N'th inductance L_{N} in series; all series branches being in parallel except the second-order series branche and the third-order series; the second-order series branche being in parallel with the first resistance R₁, the third-order series branche being in parallel with the first inductance L₁; the parallel branche circuit in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series with C_{N};
the second step, establishing relationships between elements of the same type in the wideband EC model: relationships between R₂˜R_{N} and R₁, L₂˜L_{N} and L₁, C₂˜C_{N} and C₁, G₂˜G_{N-1} and G₁;
the third step, establishing relationships between elements of the same type in the L-type EC model and the wideband EC model: relationships between R₀ and R₁, L₀ and L₁, C₀ and C₁, G₀ and G₁; and
the fourth step, obtaining R₀, L₀, C₀, and G₀ from the Telegraph equation and the linear function, and gating R₂˜R_{N}, L₂˜L_{N}, C₂˜C_{N}, and G₂˜G_{N-1}.

In the method of the present invention, wherein in the first step, the L-type EC model includes:
a series branche at low frequency, comprising R₀ and L₀ in series; and
a parallel branche at low frequency in parallel with the series branche at low frequency, comprising C₀ and G₀ in series or in parallel.

In the method of the present invention, wherein in the second step, the method for establishing relationships between elements of the same type in the wideband EC model includes:
the first, obtaining the first series impedances equation and the first parallel conductances equation from the L-type EC model by the transmission line equation;
the second, (1) obtaining coefficients for elements by unfolding the first series impedances equation according to Taylor's formula

$$\frac{tanh ( x )}{x} :$$

each first-class expansion term having one first-class coefficient; regarding the n'th first-class coefficient Kₙ as the value of Rₙ/R₁ and Lₙ/L₁; or taking valuations from (0.8Kₙ, 1.2Kₙ) as the value of Rₙ/R₁ and Lₙ/L₁; and (2) further obtaining coefficients for elements by unfolding the first parallel conductances equation according to Taylor's formula each

$$\frac{coth ( x )}{x} :$$

each second-class expansion term having one second-class coefficient; and further regarding the (n−1)'th second-class coefficient Fₙ₋₁ as the value of Cₙ/C₁ and Gₙ₋₁/G₁, and 1/5 as the value of C₂/C₁, or taking valuations from (0.8Fₙ₋₁, 1.2Fₙ₋₁) as the value of Cₙ/C₁ and Gₙ₋₁/G₁, and from (4/25, 6/25) as the value of C₂/C₁.

In the method of the present invention, wherein in the third step, the method for establishing relationships between elements of the same type in the L-type EC model and the wideband EC model includes:
the first, obtaining the third series impedances equation and the third parallel conductances equation from the L-type EC model by the topology model;
the second, obtaining relationships between R₀ and R₁, L₀ and L₁ by making the second series impedances equation equal to the third series impedances equation at the low frequency conditions of ω→0; and further obtaining relationships between C₀ and C₁, G₀ and G₁ by making the second parallel conductances equation equal to the third parallel conductances equation at the low frequency conditions of ω→0.

In the method of the present invention, wherein in the second step, further includes:
establishing relationships between G₂ and G₁: G₂/G₁=A;
determining whether A needs to be corrected according to the bulk conductivity σ of the substrate of the passive device; if so, A is numerically corrected according to the empirical range.

In the method of the present invention, wherein if σ=0, A does not need to be corrected; if σ>0, A is numerically corrected according to the empirical range.

In the method of the present invention, wherein in the fourth step, the passive device is simulated by 3D full wave or tested by experiment, and the telegraph equation is constructed; the linear function of the telegraph equation and frequency band f is constructed, and the slope of the linear function is extracted, that is, R₀, L₀, C₀, G₀.

In the method of the present invention, wherein when N=2, R₁/R₀=4, R₂/R₀=4/3; L₁/L₀=16/19, L₂/L₀=16/57; C₁/C₀=6/5, C₂/C₀=6/25; G₁/G₀=36/25.

In the method of the present invention, wherein when N=3, R₁/R₀=4, R₂/R₀=4/3, R₃/R₀=8/15; L₁/L₀=16/19, L₂/L₀=16/57, L₃/L₀=32/285; C₁/C₀=6/5, C₂/C₀=6/25, C₃/C₀=2/5; G₁/G₀=36/25, G₂/G₀=12/25.

The present invention further provides a system of parameter extraction, including:
the first-establishing unit, used for establishing an L-type EC model at low frequency of the passive device, and a wideband EC model; the L-type EC model comprising an EC resistance R₀, an EC inductance L₀, an EC capacitance C₀, and an EC conductance G₀; the wideband EC model comprising a series branche circuit and a parallel branche circuit; the series branche circuit comprising N series branches, N≥2; all series branches having the same elements; the N'th-order series branche comprising the N'th resistance Rx and the N'th inductance Lx in series; all series branches being in parallel except the second-order series branche and the third-order series; the second-order series branche being in parallel with the first resistance R₁, the third-order series branche being in parallel with the first inductance L₁; the parallel branche circuit in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series with C_{N};
the second-establishing unit, used for establishing relationships between elements of the same type in the wideband EC model: relationships between R₂˜R_{N} and R₁, L₂˜L_{N} and L₁, C₂˜C_{N} and C₁, G₂˜G_{N-1} and G₁;
the third-establishing unit, used for establishing relationships between elements of the same type in the L-type EC model and the wideband EC model: relationships between R₀ and R₁, L₀ and L₁, C₀ and C₁, G₀ and G₁; and
a obtaining unit, used for obtaining R₀, L₀, C₀, and G₀ from the Telegraph equation and the linear function, and gating R₂˜R_{N}, L₂˜L_{N}, C₂˜C_{N}, and G₂˜G_{N-1}.

In the system of the present invention, wherein the first-establishing unit includes:
a series branche at low frequency, including R₀ and L₀ in series; and
a parallel branche at low frequency in parallel with the series branche at low frequency, including C₀ and G₀ in series or in parallel.

In the system of the present invention, wherein the second-establishing unit is further used for:
the first, obtaining the first series impedances equation and the first parallel conductances equation from the L-type EC model by the transmission line equation;
the second, (1) obtaining coefficients for elements by unfolding the first series impedances equation according to Taylor's formula

$$\frac{tanh ( x )}{x} :$$

each first-class expansion term having one first-class coefficient; regarding the n'th first-class coefficient Kₙ as the value of Rₙ/R₁ and Lₙ/L₁; or taking valuations from (0.8Kₙ, 1.2Kₙ) as the value of Rₙ/R₁ and Lₙ/L₁; and (2) further obtaining coefficients for elements by unfolding the first parallel conductances equation according to Taylor's formula

$$\frac{coth ( x )}{x} :$$

each second-class expansion term having one second-class coefficient; and further regarding the (n−1)'th second-class coefficient Fₙ₋₁ as the value of Cₙ/C₁ and Gₙ₋₁/G₁, and 1/5 as the value of C₂/C₁, or further taking valuations from (0.8Fₙ₋₁, 1.2Fₙ₋₁) as the value of Cₙ/C₁ and Gₙ₋₁/G₁, and from (4/25, 6/25) as the value of C₂/C₁.

In the system of the present invention, wherein the third-establishing unit is further used for:
the first, obtaining the third series impedances equation and the third parallel conductances equation from the L-type EC model by the topology model;
the second, obtaining relationships between R₀ and R₁, L₀ and L₁ by making the second series impedances equation equal to the third series impedances equation at the low frequency conditions of ω→0;
obtaining relationships between C₀ and C₁, G₀ and G₁ by making the second parallel conductances equation equal to the third parallel conductances equation at the low frequency conditions of ω→0.

In the system of the present invention, wherein the second-establishing unit is further used for:
establishing relationships between G₂ and G₁: G₂/G₁=A;
determining whether A needs to be corrected according to the bulk conductivity o of the substrate of the passive device; if so, A is numerically corrected according to the empirical range.

In the system of the present invention, wherein if σ=0, A does not need to be corrected; if σ>0, A is numerically corrected according to the empirical range.

In the system of the present invention, wherein the obtaining unit is further used for: the passive device being simulated by 3D full wave or tested by experiment, and the telegraph equation being constructed; the linear function of the telegraph equation and frequency band f being constructed, and the slope of the linear function being extracted, that being, R₀, L₀, C₀, G₀.

In the system of the present invention, wherein when N=2, R₁/R₀=4, R₂/R₀=4/3; L₁/L₀=16/19, L₂/L₀=16/57; C₁/C₀=6/5, C₂/C₀=6/25; G₁/G₀=36/25.

In the system of the present invention, wherein when N=3, R₁/R₀=4, R₂/R₀=4/3, R₃/R₀=8/15; L₁/L₀=16/19, L₂/L₀=16/57, L₃/L₀=32/285; C₁/C₀=6/5, C₂/C₀=6/25, C₃/C₀=2/5; G₁/G₀=36/25, G₂/G₀=12/25.

Compared with the prior art, the present invention has the following beneficial effects.

1. The wideband EC model is suitable for characterizing the RF characteristics of wideband devices, covering all passive devices, such as transmission lines, capacitors, inductors, transformers, TSV, BGA, etc.

2. On the one hand, the coefficient relationship between the same type elements in the wideband EC model is established, so that the existing independent parameters in the wideband EC model become dependent elements, effectively reducing the number of parameter extraction and shortening the time of parameter extraction. On the other hand, establishing the coefficient relationship between the same type elements in the low-band L-type EC model and the wide-band EC model can improve the accuracy of parameter extraction, reduce the difficulty of parameter extraction and improve the efficiency of circuit design, which has a good application prospect and commercial development value. The invention uses telegraph equation and linear function to obtain R₀, L₀, C₀ and G₀, and the obtained values are more accurate.

### BRIEF DESCRIPTION OF THE DRAWINGS

FIG. 1 is a circuit of a wideband EC model when N=2, according to the first embodiment of the present invention.

FIG. 2 is similar to FIG. 1 when N=3.

FIG. 3 is similar to FIG. 2 when N>3.

FIG. 4 is a flow diagram of a method of parameter extraction based on the wideband EC model, according to the second embodiment of the present invention.

FIG. 5 is one circuit of an L-type EC model at low frequency of the passive device, according to the third embodiment of the present invention.

FIG. 6 is similar to FIG. 5, but showing the other circuit of the L-type EC model, according to the fourth embodiment of the present invention.

FIG. 7 is a structure diagram of the transmission line CPW used in the third and the fourth embodiments.

FIG. 8 is a circuit of two equivalent circuit models constructed by the transmission line CPW in FIG. 7.

FIG. 9 is a comparison diagram of simulation data between the HFSS full-wave and the wideband EC model in the third embodiment.

FIG. 10 is a comparison diagram between experimental test data and the wideband EC model simulation data in the fourth embodiment.

### DETAILED DESCRIPTION OF PREFERRED EMBODIMENTS

The present invention will now be described more specifically with reference to the following embodiments. It is to be noted that the following descriptions of preferred embodiments of this invention are presented herein for illustration and description only. It is not intended to be exhaustive or to be limited to the precise disclosed form.

It should be noted that when a component is said to be installed in another component, it can be directly on the other component or it can also exist in a resident component. When a component is considered to be set on another component, it may be set directly on the other component or there may also be a centered component. When a component is considered to be fixed to another component, it may be fixed directly to another component or there may also be a centered component.

Unless otherwise defined, all technical and scientific terms used herein have the same meaning as would normally be understood by a person skilled in the technical field belonging to the present invention. The terms used herein in the specification of the invention are for the purpose of describing specific embodiments only and are not intended to limit the invention. The term or/and as used herein includes any and all combinations of one or more related listed items.

The first embodiment of the present invention is as hereunder mentioned.

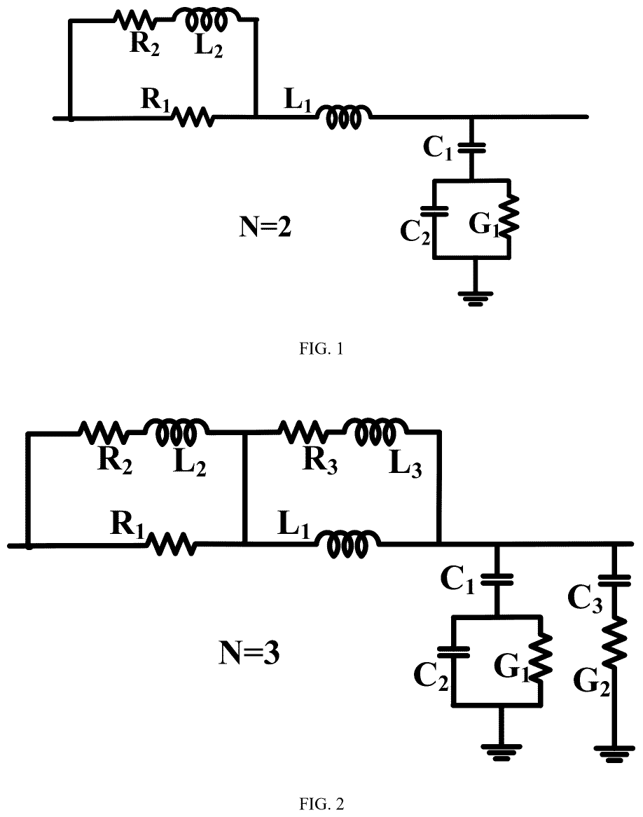

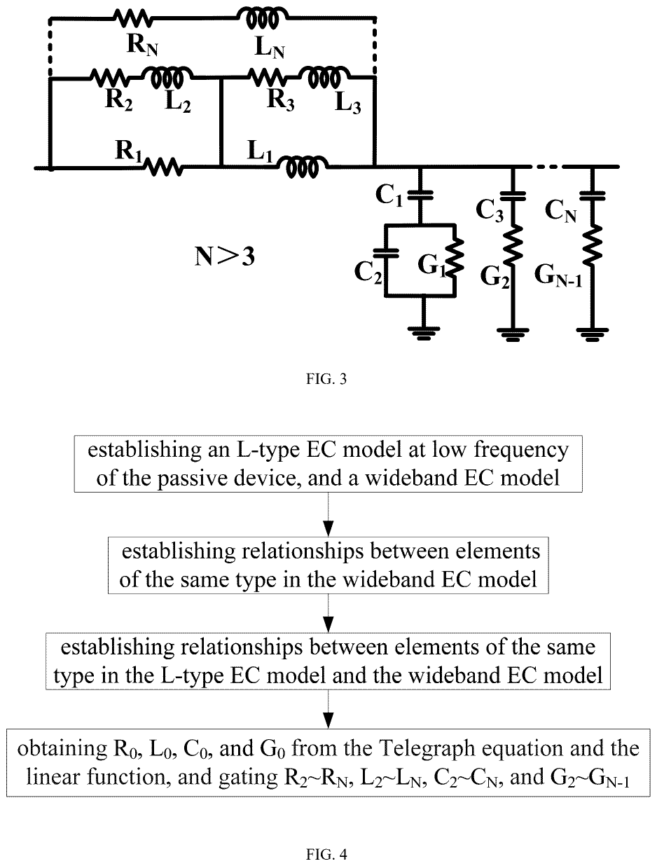

The present invention provides a wideband EC model of a passive device. The wideband EC model includes a series branche circuit and a parallel branche circuit in series. So the series branche circuit is in series with the series branche circuit. The series branche circuit includes N series branches, N≥2, and the parallel branche circuit includes N−1 parallel branches which are all in parallel. Such as, referring to FIG. 1, N=2; referring to FIG. 2, N=3; referring to FIG. 3, N>3.

All series branches have the same elements. The N'th-order series branche includes the N'th resistance R_{N} and the N'th inductance L_{N} in series. All series branches are in parallel except the second-order series branche and the third-order series. The second-order series branche is in parallel with the first resistance R₁, and the third-order series branche is in parallel with the first inductance L₁.

All parallel branches have the same elements except the first-order parallel branche. The first-order parallel branche includes the first capacitance C₁, the second capacitance C₂ in series with C₁, and the first conductance G₁ in parallel with C₂. The (N−1)'th-order parallel branche includes the N'th capacitance C_{N} and the (N−1)'th inductance conductance G_{N-1} in series.

When N=2, referring to FIG. 1, the second-order series branche is in parallel with R₁, and the application frequency range of the wideband EC model is from DC to 50 GHz accordingly. DC to 50 GHz also means 0 to 50 GHz.

When N=3, referring to FIG. 2, the second-order series branche is in parallel with R₁, and the third-order series branche is in parallel with L₁. Then, the application frequency range of the wideband EC model is from DC to 160 GHz accordingly.

When N>3, referring to FIG. 3, all series branches are in parallel except the second-order series branche and the third-order series. The second-order series branche is in parallel with R₁, the third-order series branche is in parallel with L₁, and the N'th-order series branche is in parallel with the first-order series branche. Then, the application frequency range of the wideband EC model is from up to 160 GHz accordingly.

The wideband EC model provided in the first embodiment can cover all passive devices: capacitors, inductors, resistors, RDL, BGA, TSV, transformer transform, etc.

The second embodiment of the present invention is as hereunder mentioned.

Referring to FIG. 4, FIG. 4 is a flow diagram of a method of parameter extraction based on the wideband EC model shown in the first embodiment of the present invention. The method of parameter extraction based on the wideband EC model includes following steps.

The first step, establish an L-type EC model at low frequency of the passive device, and the wideband EC model. The L-type EC model includes four elements, such as an EC resistance R₀, an EC inductance L₀, an EC capacitance C₀, and an EC conductance G₀.

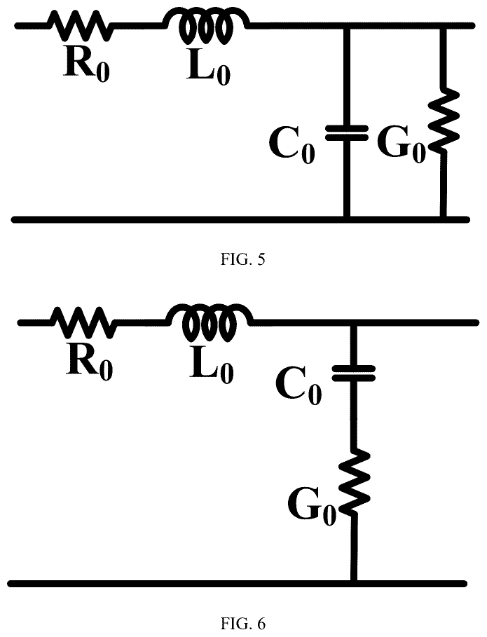

The L-type EC model has two types respectively correspond to FIGS. 5 and 6. The L-type EC model includes a series branche at low frequency and a parallel branche at low frequency in parallel. The series branche at low frequency includes R₀ and L₀ in series, and the parallel branche at low frequency includes C₀ and G₀ in series or in parallel. In FIG. 5, R₀ and L₀ in series, but C₀ and G₀ in parallel. In FIG. 6, R₀ and L₀ in series, and C₀ and G₀ in series, too.

The second step, establish relationships between elements of the same type in the wideband EC model: relationships between R₂˜R_{N} and R₁, L₂˜L_{N} and L₁, C₂˜C_{N} and C₁, G₂˜G_{N-1} and G₁.

In the second step, the method for establishing relationships between elements of the same type in the wideband EC model includes two steps.

(1) obtain the first series impedances equation and the first parallel conductances equation from the L-type EC model by the transmission line equation.

Generally, is to construct the solution equation and impedance equation of the transmission line voltage and current wave of the low-frequency L-type EC model, and put the transmission line impedance equation under the boundary condition of short circuit at the input end and open at the output end, and obtain the first series impedances equation and the first parallel conductances equation.

(2) obtain coefficients for elements by unfolding the first series impedances equation according to Taylor's formula

$$\frac{tanh ( x )}{x} :$$

each first-class expansion term having one first-class coefficient.

It should be noted that several expansion items of each first-class should be sorted in order from smallest to largest according to the size of the number of times.

There are two types of values of Rₙ/R₁, Lₙ/L₁ that can be determined: the first type, regard the n'th first-class coefficient Kₙ as the value of Rₙ/R₁ and Lₙ/L₁; the second type, take valuations from (0.8Kₙ, 1.2Kₙ) as the value of Rₙ/R₁ and Lₙ/L₁.

Further obtain coefficients for elements by unfolding the first parallel conductances equation according to Taylor's formula

$$\frac{coth ( x )}{x} :$$

each second-class expansion term having one second-class coefficient.

It should be noted that several expansion items of each second-class should be sorted in order from smallest to largest according to the size of the number of times.

There are also two types of values of C₂/C₁, Cₙ/C₁, G_{n′-1}/G₁ that can be determined: the first type, regard the n'th second-class coefficient Fₙ₋₁ as the value of Cₙ/C₁ and Gₙ₋₁/G₁, and 1/5 as the value of C₂/C₁; the second type, take valuations from (0.8Fₙ₋₁, 1.2Fₙ₋₁) as the value of Cₙ/C₁ and Gₙ₋₁/G₁, and from (4/25, 6/25) as the value of C₂/C₁.

In the present invention, the first-class coefficients and second-class coefficients are fixed and satisfy the following relations: K₁<1, K₂<K₁, . . . , K_{N}<K_{N-1}; F₁<1, F₂<F₁, . . . , F_{N′-1}<F_{N′-2}.

Therefore, if the first type of coefficient relationship is determined, a set of fixed coefficients can be obtained. In other words, in this case, the actual value of N in the wideband equivalent circuit model only affects the number of fixed coefficients in this set. If the substrate of the passive device is an insulating material, the results obtained by following the above steps are accurate.

However, if the substrate of the passive device is A semiconductor material (such as low-resistance silicon material), the coefficient relationship between G2 and G1 is set to G2/G1=A according to the above steps.

The accuracy of this A is related to the bulk conductivity o of the substrate. In general, whether A needs to be corrected is determined according to the bulk conductivity o of the substrate of the passive device. If so, A is numerically corrected according to the empirical range.

If σ=0, A does not need to be corrected; if σ>0, A is numerically corrected according to the empirical range. For example, if σ=1, A must be modified, and the value ranges from 450 to 1200. If σ=2, A must be modified, and the value ranges from (200,700). If σ=3, A must be modified, and the value ranges from (150,350).

The third step, establish relationships between elements of the same type in the L-type EC model and the wideband EC model: relationships between R₀ and R₁, L₀ and L₁, C₀ and C₁, G₀ and G₁.

In the third step, the method for establishing relationships between elements of the same type in the L-type EC model and the wideband EC model includes two steps.

(1) obtain the third series impedances equation and the third parallel conductances equation from the L-type EC model by the topology model.

(2) obtain relationships between R₀ and R₁, L₀ and L₁ by making the second series impedances equation equal to the third series impedances equation at the low frequency conditions of ω→0; and further obtain relationships between C₀ and C₁, G₀ and G₁ by making the second parallel conductances equation equal to the third parallel conductances equation at the low frequency conditions of ω→0.

In the present invention, the real and imaginary part of the second and the third series impedances equations are separately equivalent at the boundary conditions of ω→0, to obtain relationships between R₀ and R₁, L₀ and L₁. The real and imaginary part of the second and the third parallel conductances equations are separately equivalent at the boundary conditions of ω→0, to obtain relationships between C₀ and C₁, G₀ and G₁.

The fourth step, obtain R₀, L₀, C₀, and G₀ from the Telegraph equation and the linear function, and gate R₂˜R_{N}, L₂˜L_{N}, C₂˜C_{N}, and G₂˜G_{N-1}.

In the fourth step, the passive device is simulated by 3D full wave or tested by experiment, and the telegraph equation is constructed; the linear function of the telegraph equation and frequency band f is constructed, and the slope of the linear function is extracted, that is, R₀, L₀, C₀, G₀.

The telegraph equation is shown as:

$$\{ \begin{matrix}R ( f ) = Re [ γ ( f ) \times Z ( f ) ] \\ L ( f ) = \frac{Im [ γ ( f ) \times Z ( f ) ]}{ω} \\ G ( f ) = Re [ γ ( f ) / Z ( f ) ] \\ C ( f ) = \frac{Im [ γ ( f ) / Z ( f ) ]}{ω}\end{matrix}$$

In the formular, ω=2πf; Z(f) represents the impedance and can also be written as an equation related to the frequency band f:

$$Z ( f ) = {Z}_{0} \sqrt{\frac{{( 1 + {S}_{11} )}^{2} - {S}_{21}^{2}}{{( 1 - {S}_{11} )}^{2} - {S}_{21}^{2}}} ,$$

Z₀ is the impedance reference value; γ(f) represents the propagation constant and can also be written as an equation related to the frequency band f:

$$γ ( f ) = \frac{1}{l} ln ( \frac{1 - {S}_{11}^{2} + {S}_{21}^{2}}{2 {S}_{21}} \pm K ) ,$$

l is the length of the passive device; K is the intermediate coefficient:

$$K = \sqrt{\frac{{( 1 - {S}_{11}^{2} + {S}_{21}^{2} )}^{2} - {( 2 {S}_{11} )}^{2}}{{( 2 {S}_{21} )}^{2}}} ,$$

S₁₁ and S₂₁ both are S coefficients.

Then, the linear function idea is used to find the linear relationship between the coefficients: the linear function of telegraph equation and f is constructed, and the slope of the linear function is extracted, that is, R₀, L₀, C₀, G₀.

The linear function is shown as:

$$\{ \begin{matrix}[ {R}_{0} , {σ}_{1} ] = l \times linear [ R ( f ) \times f , f ] \\ [ {L}_{0} , {σ}_{2} ] = l \times linear [ L ( f ) / ( 2 π ) , f ] \\ [ {C}_{0} , {σ}_{3} ] = l \times linear [ C ( f ) / ( 2 π ) , f ] \\ [ {G}_{0} , {σ}_{4} ] = l \times linear [ G ( f ) \times f , f ]\end{matrix}$$

In the formular, σ₁˜σ₄ is the frequency range used to obtain the slope of the linear function.

The slope of the l×linear[R(f)×f, f] at σ₁ is R₀; the slope of the l×linear[L(f)/(2π), f] at σ₂ is L₀; the slope of the l×linear[C(f)/(2π), f] at σ₃ is C₀; the slope of the l×linear G(f)×f, f at σ₄ is G₀.

The fourth step can be completed by 3D full-wave simulation of passive devices, or by experimental testing. Among them, 3D full wave simulation can be implemented using 3D full wave simulation software (such as HFSS, CST, etc.). The experimental test is carried out by the probe system.

As the coefficient relations between R₀ and R₁, L₀ and L₁, C₀ and C₁, G₀ and G₁ have been obtained in the second step, the coefficient relations between R₂-Rₙ and R₁, L₂-L_{N} and L₁, C₂-C_{N} and C₁, G₂-G_{N-1} and G₁ have also been obtained. Then R₁˜R_{N}, L₁˜L_{N}, C₁˜C_{N}, and G₁-G_{N-1} can be directly converted based on the extracted R₀, L₀, C₀, and G₀. This process is also simple and fast.

If the coefficient relationships between the same type elements in the wideband equivalent circuit model is determined by the first coefficient relationship, a set of fixed coefficients can be obtained. The coefficient relationship between the same type elements in the low-band L-type EC model and the wide-band EC model can also be regarded as a set of fixed coefficients. Then, this extraction method can actually obtain the exact coefficient relationship between each element of the wide-band EC model and the four lumped elements of the low-band L-type EC model, and this exact coefficient relationship can be used directly.

If the substrate of the passive device is an insulating material, it is processed according to the above steps, and the first coefficient relationship is determined, and the exact coefficient relationships can be obtained as follows.

When N=2, R₁/R₀=4, R₂/R₀=4/3; L₁/L₀=16/19, L₂/L₀=16/57; C₁/C₀=6/5, C₂/C₀=6/25; G₁/G₀=36/25.
when N>3, R₁/R₀=4, R₂/R₀=4/3, R₃/R₀=8/15; L₁/L₀=16/19, L₂/L₀=16/57, L₃/L₀=32/285; C₁/C₀=6/5, C₂/C₀=6/25, C₃/C₀=2/5; G₁/G₀=36/25, G₂/G₀=12/25.
when N>3, on the basis of N=3, R₄/R₀˜R_{N}/R₀, L₄/L₀˜L_{N}/L₀, C₄/C₀˜C_{N}/C₀, G₃/G₀˜C_{N-1}/G₀ are added.

The third embodiment of the present invention is as hereunder mentioned.

The third embodiment is an example of the parameter extraction method of the second embodiment.

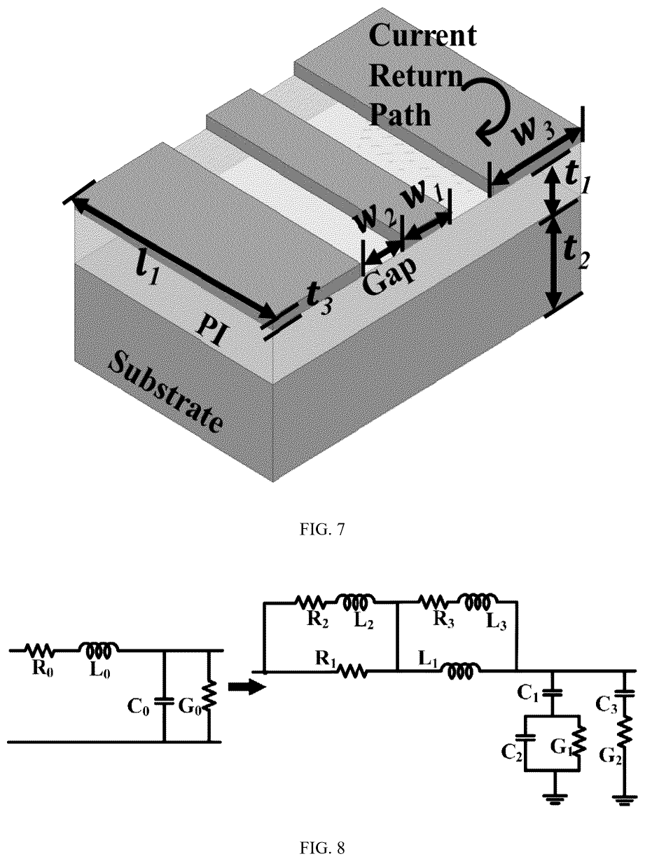

Referring to FIG. 7, the passive device in the present invention is a transmission line CPW, and its structure is shown in FIG. 7: glass substrate, polyimide layer and metal layer successively from bottom to bottom (reflux ground plane on both sides, signal line in the middle). In FIG. 7, t₁ is the thickness of polyimide layer; t₂ is the thickness of glass substrate; t₃ is the thickness of the metal layer l₁ is the width of the metal layer; w₂ is the distance between the signal line and the return ground plane. w₃ is the length of the return ground plane; w₁ is the length of the signal cable.

Take 10 μm for t₁; take 300 μm for t₂; take 5 μm for t₃; take 700 μm for l₁; take 5 μm for w₂: take 500 μm for w₃; take one of 20, 30, 40, 50, 60, 100 μm for w₁. That is to say, six different sizes of transmission line CPW are selected for this specific example.

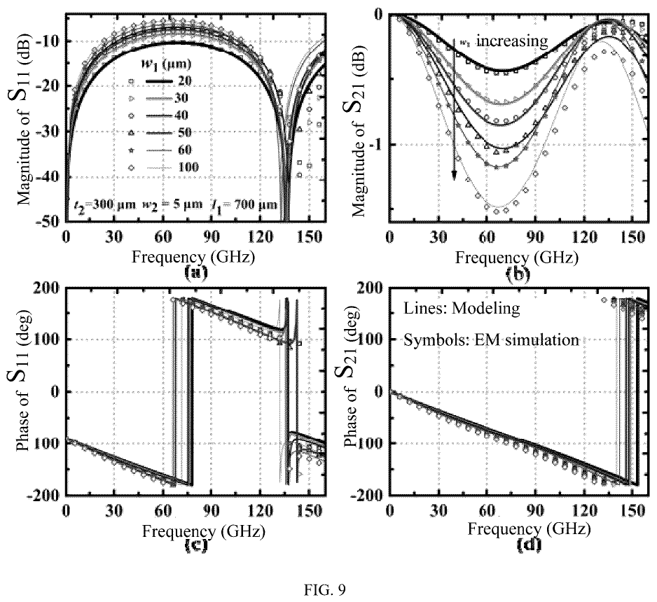

The EC model as shown in FIG. 8 is constructed: the left part of FIG. 8 is the low-band L-type EC model, and the right part is the wide-band EC model. So, the first-order series branche includes R₁ and L₁, the second-order series branche includes R₂ and L₂, and the third-order series branche includes R₃ and L₃. The first-order parallel branche includes C₁, C₂, and G₁, and the second-order parallel branche includes C₃ and G₂. C₁ and C₂ are in series.

Establish relationships between elements of the same type in the wideband EC model: relationships between R₂˜R₃ and R₁, L₂˜L₂ and L₁, C₂˜C₃ and C₁, G₂ and G₁.

(1.1) The transmission line voltage-current wave solution equation and the impedance equation of the model on the left of FIG. 8 are constructed:

$$v ( x ) - {V}_{1} {e}^{- γ x} + {V}_{2} {e}^{γ x}$$

$$i ( x ) = {I}_{1} {e}^{- γ x} + - {I}_{2} {e}^{γ x}$$

In the formula, v(x) represents the voltage traveling wave solution; i(x) A represents the electropopular wave solution; e^{γx} indicates that the electromagnetic wave travels in the direction of +x; e^{γx} indicates that the electromagnetic wave travels in the direction of −x; γ represents propagation constant; both V₁ and V₂ represent the voltage of the transmission line; both I₁ and I₂ represent the current of the transmission line.

The impedance equation Zᵢₙ(x) of transmission line is obtained: Zᵢₙ(x)=v(x)/i(x).

(1.2) The impedance equation of the transmission line is placed under the boundary conditions of short circuit at the input end and open at the output end, and then the first series impedances equation and the first parallel admittances equation are obtained:

$$Z = \frac{1}{γ x} \frac{{e}^{- γ x} - {e}^{γ x}}{{e}^{- γ x} + {e}^{γ x}}$$

$$Y = \frac{Z}{γ} \frac{{e}^{- γ x} + {e}^{γ x}}{{e}^{- γ x} - {e}^{γ x}}$$

In the formula, Z represents the first series impedances equation, which reflects the impedance of the series branch in the low frequency band; Y represents the first parallel admittances equation, which reflects the admittance of the parallel branch in the low frequency band.

(1.3) The first series impedances equation is unfolded according to Taylor's formula

$$\frac{tanh ( x )}{x} :$$

$$Z = \frac{1}{γ x} \frac{{e}^{- γ x} - {e}^{γ x}}{{e}^{- γ x} + {e}^{γ x}} = \frac{tanh ( γ x )}{γ x} = 1 - \frac{1}{3} {x}^{2} + \frac{2}{15} {x}^{4} - \frac{17}{315} {x}^{6} + …$$

The first parallel conductances equation is unfolded according to Taylor's formula

$$\frac{coth ( x )}{x} :$$

$$Y = \frac{Z}{γ} \frac{{e}^{- γ x} + {e}^{γ x}}{{e}^{- γ x} - {e}^{γ x}} = \frac{coth ( γ x )}{γ x} = {x}^{- 2} + \frac{1}{3} - \frac{1}{45} {x}^{2} + \frac{2}{945} {x}^{4} - …$$

Since the left part model and the right part model in FIG. 8 are correspond, it is for the two formulas in (1.3): the left part of the formula represents the left part model in FIG. 8, and the right part of the formula represents the right part model in FIG. 8. The coefficient relationship of the right part model in FIG. 8 can be obtained from the right part of the formula: R₂/R₁=1/3, L₂/L₁=1/3, R₃/R₁=2/15, L₃/L₁=2/15, C₃/C₁=1/3, G₂/G₁=1/3, and C₂/C₁=1/5.

Then the relations between R₀ and R₁, L₀ and L₁, C₀ and C₁, G₀ and G₁ are established.

(2.1) According to the components specifically included in the left part of the model in FIG. 8, the second series impedances equation and the second parallel admittances equation are written. The second series impedances equation reflects the impedance of the series branch in the low frequency band, and the second parallel admittances equation reflects the admittance of the parallel branch in the low frequency band.

According to the specific components included in the right part of the model in FIG. 8, the third series impedances equation and the third parallel admittances equation are written. The third series impedances equation reflects the impedance of the UWB series branch, and the third parallel admittances equation reflects the admittance of the UWB parallel branch.

(2.2) Since the real and imaginary part of Zₐ (the second series impedances equation) are separately equivalent to those of Z_{b} (the third series impedances equation) at the boundary conditions of ω→0, these formulae are introduced as follows:

$$Re ( {Z}_{a} ) = {lim}_{ω \to 0} Re ( {Z}_{b} )$$

$$Im ( {Z}_{a} ) = {lim}_{ω \to 0} Im ( {Z}_{b} )$$

The coefficients of parameters R₁ and L₁ (i=1, 2, 3) in the two series branches, are calculated as:

$${R}_{1} / {R}_{0} = 4 , {R}_{2} / {R}_{0} = 4 / 3 , {R}_{3} / {R}_{0} = 8 / 15 ,$$

$${L}_{1} / {L}_{0} = 16 / 19 , {L}_{2} / {L}_{0} = 16 / 57 , {L}_{3} / {L}_{0} = 32 / 285$$

Analogously, since the real part and imaginary part of Yₐ (the second parallel admittances equation) and Y_{b} (the third parallel admittances equation) are equivalent at ω→0 condition, these formulae are introduced as follows:

$$Re ( {Y}_{a} ) = {lim}_{ω \to 0} Re ( {Y}_{b} )$$

$$Im ( {Y}_{a} ) = {lim}_{ω \to 0} lm ( {Y}_{b} )$$

So some coefficients can be obtained as follows:

$${C}_{1} / {C}_{0} = 6 / 5 , {C}_{2} / {C}_{0} = 6 / 25 , {C}_{3} / {C}_{0} = 2 / 5 , {G}_{1} / {G}_{0} = 36 / 25 , {G}_{2} / {G}_{0} = 12 / 25$$

Since glass material is an insulating material and its bulk conductivity σ=0 S/m, the relation obtained according to the parameter extraction method in the second embodiment does not need to be corrected.

Then, HFSS software is used to extract the four lumped elements R₀, L₀, C₀ and G₀ in the left model of FIG. 8 according to the fourth step, and then the values of the eleven elements in the right model are obtained.

The third embodiment is also verified by simulation.

Based on the actual size of transmission line CPW, the simulation structure of transmission line CPW was constructed in HFSS software. In other words, the simulation structures of the above six transmission line CPW were constructed. Then set the simulation frequency band 110 MHz˜160 GHz to obtain the HFSS full-wave simulation data.

The EC model shown in FIG. 8 was constructed for transmission line CPW in ADS or ICCAP software. Model parameters were set according to the conclusion: R₁/R₀=4, R₂/R₀=4/3, R₃/R₀=8/15, L₁/L₀=16/19, L₂/L₀=16/57, L₃/L₀=32/285, C₁/C₀=6/5, C₂/C₀=6/25, C₃/C₀=2/5, G₁/G₀=36/25, G₂/G₀=12/25. The specific values of R₀, L₀, C₀ and G₀ were also set according to the conclusion. Then the EC model with set parameters was simulated, and the simulation data of the EC model was obtained.

Compared the HFSS full-wave simulation data with the EC model simulation data, and compared the S-parameters of the two (including the amplitude of S₁₁, the phase of S₁₁, the amplitude of S₂₁, and the phase of S₂₁), and the results were shown in FIG. 9.

Referring FIG. 9, where dots represent HFSS full-wave simulation data, using different symbols to represent different types of transmission line CPW. The Line represents EC model simulation data, using different shades to represent different types of transmission line CPW.

FIG. 9(a) shows a comparison of the magnitude of S₁₁. FIG. 9(b) shows the comparison of the amplitude of S₂₁. FIG. 9(c) shows the phase comparison of S₁₁. FIG. 9(d) shows the phase comparison of S₂₁. It could be seen that the consistency between the data was high, which proves the accuracy of the method in the second embodiment.

The fourth embodiment of the present invention is as hereunder mentioned.

The fourth embodiment exposes another concrete example of the parameter extraction method of the second embodiment.

Referring to FIG. 7, the fourth embodiment is similar with the third embodiment, and four sizes of the transmission line CPW are selected as the passive device.

The first size is shown: take 10 μm for t₁; take 300 μm for t₂; take 5 μm for t₃; take 1100 μm for l₁; take 22 μm for w₂: take 500 μm for w₃; take 100 μm for w₁.

The second size is shown: take 10 μm for t₁; take 300 μm for t₂; take 5 μm for t₃; take 700 μm for l₁; take 22 μm for w₂: take 500 μm for w₃; take 100 μm for w₁.

The third size is shown: take 10 μm for t₁; take 300 μm for t₂; take 5 μm for t₃; take 1500 μm for l₁; take 22 μm for w₂: take 1500 μm for w₃; take 100 μm for w₁.

The third size is shown: take 10 μm for t₁; take 300 μm for t₂; take 5 μm for t₃; take 700 μm for l₁; take 22 μm for w₂: take 500 μm for w₃; take 100 μm for w₁.

The specific process of applying the method of parameter extraction described in the second embodiment, is similar to that of the third embodiment. Then it will not repeated in the fourth embodiment.

Finally relationships is obtained: R₂/R₁=1/3, L₂/L₁=1/3, R₃/R₁=2/15, L₃/L₁=2/15, C₃/C₁=1/3, G₂/G₁=1/3, C₂/C₁=1/5; R₁/R₀=4, R₂/R₀=4/3, R₃/R₀=8/15, L₁/L₀=16/19, L₂/L₀=16/57, L₃/L₀=32/285; C₁/C₀=6/5, C₂/C₀=6/25, C₃/C₀=2/5, G₁/G₀=36/25, G₂/G₀=12/25.

HFSS software was used to extract the four lumped elements R₀, L₀, C₀ and G₀ in the left model of FIG. 8 according to the fourth step, and then the values of the eleven elements in the right model were obtained.

The fourth embodiment is also verified by simulation.

First, four kinds of transmission line CPW were processed according to the size specifications, and then four CPW samples were tested with the probe system in the test band of 110 MHz˜110 GHz to obtain the experimental test data of the probe.

Second, the EC model shown in FIG. 8 was constructed for transmission line CPW in ADS or ICCAP software. Model parameters were set according to the conclusion: R₁/R₀=4, R₂/R₀=4/3, R₃/R₀=8/15, L₁/L₀=16/19, L₂/L₀=16/57, L₃/L₀=32/285, C₁/C₀=6/5, C₂/C₀=6/25, C₃/C₀=2/5, G₁/G₀=36/25, G₂/G₀=12/25. The specific values of R₀, L₀, C₀ and G₀ were also set according to the conclusion. Then the EC model with set parameters was simulated, and the simulation data of the EC model was obtained.

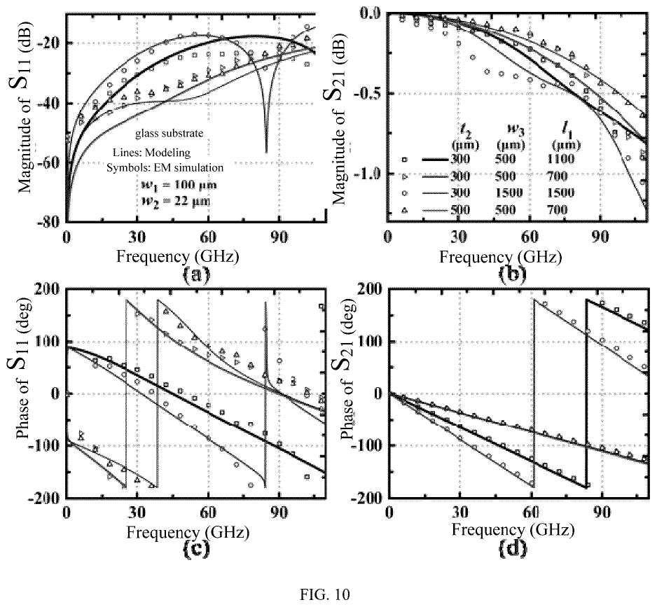

The experimental data of the probe were compared with the simulation data of the EC model, and the S-parameters of the two (including the amplitude of S₁₁, the phase of S₁₁, the amplitude of S₂₁, and the phase of S₂₁) were also compared, then the results were shown in FIG. 10.

Referring FIG. 10, dots represent probe test data, using different symbols to represent different types of transmission line CPW. The Line represents EC model simulation data, using different shades to represent different types of transmission line CPW.

FIG. 10(a) shows a comparison of the magnitude of S₁₁. FIG. 10(b) shows the comparison of the amplitude of S₂₁. FIG. 10(c) shows the phase comparison of S₁₁. FIG. 10(d) shows the phase comparison of S₂₁. It could be seen that the consistency between the data was high, which proves the accuracy of the method in the second embodiment.

The fifth embodiment of the present invention is as hereunder mentioned.

The fifth embodiment discloses a parameter extraction system for a passive device-based wideband EC model, which uses the parameter extraction method for the passive device-based wideband EC model of the second embodiment.

The system of parameter extraction includes the first-establishing unit, the second-establishing unit, the third-establishing unit, and a obtaining unit.

The first-establishing unit is used for establishing an L-type EC model at low frequency of the passive device, and a wideband EC model. The second-establishing unit is used for establishing relationships between elements of the same type in the wideband EC model: relationships between R₂˜R_{N} and R₁, L₂˜L_{N} and L₁, C₂˜C_{N} and C₁, G₂˜G_{N-1} and G₁. The third-establishing unit is used for establishing relationships between elements of the same type in the L-type EC model and the wideband EC model: relationships between R₀ and R₁, L₀ and L₁, C₀ and C₁, G₀ and G₁. The obtaining unit is used for obtaining R₀, L₀, C₀, and G₀ from the Telegraph equation and the linear function, and gating R₂˜R_{N}, L₂˜L_{N}, C₂˜C_{N}, and G₂˜G_{N-1}.

The sixth embodiment of the present invention is as hereunder mentioned.

The sixth embodiment discloses a readable storage medium in which computer program instructions are stored, and the steps of the parameter extraction method of the passive device-based wideband EC model of the second embodiment are executed when the computer program instructions are read and run by a processor. When the method in the second embodiment is applied, it can be applied in the form of software. Such as a program is designed as a computer readable storage medium that can run independently. The computer readable storage medium can be a U disk designed as a U shield, and the program is designed as an external trigger to start the whole method through the U disk.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wideband EC model of a passive device, comprising:
a series branche circuit, comprising N series branches, N≥2; all series branches having the same elements; the N'th-order series branche comprising the N'th resistance R_{N} and the N'th inductance L_{N} in series; all series branches being in parallel except the second-order series branche and the third-order series; the second-order series branche being in parallel with the first resistance R₁, the third-order series branche being in parallel with the first inductance L₁; and
a parallel branche circuit, in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series.

2. A method of parameter extraction, comprising:
the first step, establishing an L-type EC model at low frequency of the passive device, and a wideband EC model; the L-type EC model comprising an EC resistance R₀, an EC inductance L₀, an EC capacitance C₀, and an EC conductance G₀; the wideband EC model comprising a series branche circuit and a parallel branche circuit; the series branche circuit comprising N series branches, N≥2; all series branches having the same elements; the N'th-order series branche comprising the N'th resistance R_{N} and the N'th inductance L_{N} in series; all series branches being in parallel except the second-order series branche and the third-order series; the second-order series branche being in parallel with the first resistance R₁, the third-order series branche being in parallel with the first inductance L₁; the parallel branche circuit in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series with C_{N};
the second step, establishing relationships between elements of the same type in the wideband EC model: relationships between R₂˜R_{N} and R₁, L₂˜L_{N} and L₁, C₂˜C_{N} and C₁, G₂˜G_{N-1} and G₁;
the third step, establishing relationships between elements of the same type in the L-type EC model and the wideband EC model: relationships between R₀ and R₁, L₀ and L₁, C₀ and C₁, G₀ and G₁; and
the fourth step, obtaining R₀, L₀, C₀, and G₀ from the Telegraph equation and the linear function, and gating R₂˜R_{N}, L₂˜L_{N}, C₂˜C_{N}, and G₂˜G_{N-1}.

3. The method according to claim 2, wherein in the first step, the L-type EC model comprising:
a series branche at low frequency, comprising R₀ and L₀ in series; and
a parallel branche at low frequency in parallel with the series branche at low frequency, comprising C₀ and G₀ in series or in parallel.

4. The method according to claim 2, wherein in the second step, the method for establishing relationships between elements of the same type in the wideband EC model comprises:
the first, obtaining the first series impedances equation and the first parallel conductances equation from the L-type EC model by the transmission line equation;
the second, (1) obtaining coefficients for elements by unfolding the first series impedances equation according to Taylor's formula tanh(x)/x: each first-class expansion term having one first-class coefficient; regarding the n'th first-class coefficient Kₙ as the value of Rₙ/R₁ and Lₙ/L₁; or taking valuations from (0.8Kₙ, 1.2Kₙ) as the value of Rₙ/R₁ and Lₙ/L₁; and (2) further obtaining coefficients for elements by unfolding the first parallel conductances equation according to Taylor's formula coth(x)/x: each second-class expansion term having one second-class coefficient; and further regarding the (n−1)'th second-class coefficient Fₙ₋₁ as the value of Cₙ/C₁ and Gₙ₋₁/G₁, and 1/5 as the value of C₂/C₁, or taking valuations from (0.8Fₙ₋₁, 1.2Fₙ₋₁) as the value of Cₙ/C₁ and Gₙ₋₁/G₁, and from (4/25, 6/25) as the value of C₂/C₁.

5. The method according to claim 2, wherein in the third step, the method for establishing relationships between elements of the same type in the L-type EC model and the wideband EC model comprises:
the first, obtaining the third series impedances equation and the third parallel conductances equation from the L-type EC model by the topology model;
the second, obtaining relationships between R₀ and R₁, L₀ and L₁ by making the second series impedances equation equal to the third series impedances equation at the low frequency conditions of ω→0; and further obtaining relationships between C₀ and C₁, G₀ and G₁ by making the second parallel conductances equation equal to the third parallel conductances equation at the low frequency conditions of ω→0.

6. The method according to claim 2, wherein in the second step, further comprises:
establishing relationships between G₂ and G₁: G₂/G₁=A;
determining whether A needs to be corrected according to the bulk conductivity o of the substrate of the passive device; if so, A is numerically corrected according to the empirical range.

7. The method according to claim 6, wherein if σ=0, A does not need to be corrected; if σ>0, A is numerically corrected according to the empirical range.

8. The method according to claim 2, wherein in the fourth step, the passive device is simulated by 3D full wave or tested by experiment, and the telegraph equation is constructed; the linear function of the telegraph equation and frequency band f is constructed, and the slope of the linear function is extracted, that is, R₀, L₀, C₀, G₀.

9. The method according to claim 2, wherein when N=2, R₁/R₀=4, R₂/R₀=4/3; L₁/L₀=16/19, L₂/L₀=16/57; C₁/C₀=6/5, C₂/C₀=6/25; G₁/G₀=36/25.

10. The method according to claim 2, wherein when N=3, R₁/R₀=4, R₂/R₀=4/3, R₃/R₀=8/15; L₁/L₀=16/19, L₂/L₀=16/57, L₃/L₀=32/285; C₁/C₀=6/5, C₂/C₀=6/25, C₃/C₀=2/5; G₁/G₀=36/25, G₂/G₀=12/25.

11. A system of parameter extraction, comprising:
the first-establishing unit, used for establishing an L-type EC model at low frequency of the passive device, and a wideband EC model; the L-type EC model comprising an EC resistance R₀, an EC inductance L₀, an EC capacitance C₀, and an EC conductance G₀; the wideband EC model comprising a series branche circuit and a parallel branche circuit; the series branche circuit comprising N series branches, N≥2; all series branches having the same elements; the N'th-order series branche comprising the N'th resistance R_{N} and the N'th inductance L_{N} in series; all series branches being in parallel except the second-order series branche and the third-order series; the second-order series branche being in parallel with the first resistance R₁, the third-order series branche being in parallel with the first inductance L₁; the parallel branche circuit in series with the series branche circuit, and comprising N−1 parallel branches which are all in parallel; all parallel branches having the same elements except the first-order parallel branche; the first-order parallel branche comprising the first capacitance C₁, the second capacitance C₂ in series with C₁, and the first conductance G₁ in parallel with C₂; the (N−1)'th-order parallel branche comprising the N'th capacitance C_{N} and the (N−1)'th inductance conductance G_{N-1} in series with C_{N};
the second-establishing unit, used for establishing relationships between elements of the same type in the wideband EC model: relationships between R₂˜R_{N} and R₁, L₂˜L_{N} and L₁, C₂˜C_{N} and C₁, G₂˜G_{N-1} and G₁;
the third-establishing unit, used for establishing relationships between elements of the same type in the L-type EC model and the wideband EC model: relationships between R₀ and R₁, L₀ and L₁, C₀ and C₁, G₀ and G₁; and
a obtaining unit, used for obtaining R₀, L₀, C₀, and G₀ from the Telegraph equation and the linear function, and gating R₂˜R_{N}, L₂˜L_{N}, C₂˜C_{N}, and G₂˜G_{N-1}.

12. The system according to claim 11, wherein the first-establishing unit is further used for:
a series branche at low frequency, comprising R₀ and L₀ in series; and
a parallel branche at low frequency in parallel with the series branche at low frequency, comprising C₀ and G₀ in series or in parallel.

13. The system according to claim 11, wherein the second-establishing unit is further used for:
the first, obtaining the first series impedances equation and the first parallel conductances equation from the L-type EC model by the transmission line equation;
the second, (1) obtaining coefficients for elements by unfolding the first series impedances equation according to Taylor's formula tanh(x)/x: each first-class expansion term having one first-class coefficient; regarding the n'th first-class coefficient Kₙ as the value of Rₙ/R₁ and Lₙ/L₁; or taking valuations from (0.8Kₙ, 1.2Kₙ) as the value of Rₙ/R₁ and Lₙ/L₁; and (2) further obtaining coefficients for elements by unfolding the first parallel conductances equation according to Taylor's formula coth(x)/x each second-class expansion term having one second-class coefficient; and further regarding the (n−1)'th second-class coefficient Fₙ₋₁ as the value of Cₙ/C₁ and Gₙ₋₁/G₁, and 1/5 as the value of C₂/C₁, or further taking valuations from (0.8Fₙ₋₁, 1.2Fₙ₋₁) as the value of Cₙ/C₁ and Gₙ₋₁/G₁, and from (4/25, 6/25) as the value of C₂/C₁.

14. The system according to claim 11, wherein the third-establishing unit is further used for:
the first, obtaining the third series impedances equation and the third parallel conductances equation from the L-type EC model by the topology model;
the second, obtaining relationships between R₀ and R₁, L₀ and L₁ by making the second series impedances equation equal to the third series impedances equation at the low frequency conditions of ω→0;
obtaining relationships between C₀ and C₁, G₀ and G₁ by making the second parallel conductances equation equal to the third parallel conductances equation at the low frequency conditions of ω→0.

15. The system according to claim 11, wherein the second-establishing unit comprises:
establishing relationships between G₂ and G₁: G₂/G₁=A;
determining whether A needs to be corrected according to the bulk conductivity o of the substrate of the passive device; if so, A is numerically corrected according to the empirical range.

16. The system according to claim 15, wherein if σ=0, A does not need to be corrected; if σ>0, A is numerically corrected according to the empirical range.

17. The system according to claim 11, wherein the obtaining unit is further used for:
the passive device being simulated by 3D full wave or tested by experiment, and the telegraph equation being constructed; the linear function of the telegraph equation and frequency band f being constructed, and the slope of the linear function being extracted, that being, R₀, L₀, C₀, G₀.

18. The system according to claim 11, wherein when N=2, R₁/R₀=4, R₂/R₀=4/3;
L₁/L₀=16/19, L₂/L₀=16/57; C₁/C₀=6/5, C₂/C₀=6/25; G₁/G₀=36/25.

19. The system according to claim 11, wherein when N=3, R₁/R₀=4, R₂/R₀=4/3, R₃/R₀=8/15; L₁/L₀=16/19, L₂/L₀=16/57, L₃/L₀=32/285; C₁/C₀=6/5, C₂/C₀=6/25, C₃/C₀=2/5; G₁/G₀=36/25, G₂/G₀=12/25.
